(19) United States
(12) Patent Application Publication
(10) Pub. No.: US 2025/0148136 A1
(43) Pub. Date: May 8, 2025

(54) METHOD AND APPARATUS FOR IMPLEMENTING BATCH EXTRACTION OF HUMAN ANATOMICAL FEATURE PARAMETERS

(71) Applicant: THE FOURTH MEDICAL CENTER OF PLA GENERAL HOSPITAL, Beijing (CN)

(72) Inventors: Jiantao LI, Beijing (CN); Menglin WANG, Beijing (CN); Wei ZHANG, Beijing (CN); Hao ZHANG, Beijing (CN); Wanheng LIU, Beijing (CN); Cheng XU, Beijing (CN); Kaixuan WANG, Beijing (CN); Zicheng ZHANG, Beijing (CN); Yanpeng ZHAO, Beijing (CN); Daofeng WANG, Beijing (CN); Zhengfeng JIA, Beijing (CN); Weilu GAO, Beijing (CN); Meng LI, Beijing (CN); Xiaomeng REN, Beijing (CN); Wupeng ZHANG, Beijing (CN); Licheng ZHANG, Beijing (CN); Peifu TANG, Beijing (CN)

(21) Appl. No.: 18/958,516

(22) Filed: Nov. 25, 2024

Related U.S. Application Data
(63) Continuation-in-part of application No. 18/941,003, filed on Nov. 8, 2024, now abandoned.

(30) Foreign Application Priority Data
Nov. 8, 2023 (CN) 202311476948.X

(51) Int. Cl. G06F 30/10

(52) U.S. Cl. CPC G06F 30/10

(57) ABSTRACT

Provided are a method and an apparatus for implementing batch extraction of human anatomical feature parameters. The method includes: obtaining a to-be-measured sample; generating an average model; calculating a point correspondence of a spatial location formed by the average model and each to-be-measured sample; measuring each to-be-measured sample on the average model; and outputting feature parameter data of each to-be-measured sample in batch. Calculation time is reduced by combining feature point extraction with affine transformation, and corresponding points are calculated through a non-rigid registration method to achieve batch and quick measurement.

### CROSS-REFERENCE TO RELATED APPLICATION

This patent application is a continuation-in-part (CIP) application of U.S. Ser. No. 18/941,003 filed Nov. 8, 2024, and that application claims the benefit and priority of Chinese Patent Application No. 202311476948.X, filed with the China National Intellectual Property Administration on Nov. 8, 2023, the disclosures of which are incorporated by reference herein in its entirety as part of the present application.

### TECHNICAL FIELD

The present disclosure relates to the field of computer technologies, and in particular to, a method and an apparatus for implementing batch extraction of human anatomical feature parameters.

### BACKGROUND

Anatomical feature parameters of parts of a body are varied. Data-driven parameter mining and analysis is a key to implement analysis for a rule of population sample parameters. A conventional method for obtaining population parameters is data measurement for a single sample. This labor-intensive implementation manner wastes time and labor. Therefore, batch parameter generation is implemented to greatly save time cost, and is of great significance in a data-driven research and development process.

### SUMMARY

An objective of the present disclosure is to provide a method and an apparatus for implementing batch extraction of human anatomical feature parameters.

To achieve the above objective, the present disclosure adopts the following technical solution.

According to one aspect, the present disclosure provides a method for implementing batch extraction of human anatomical feature parameters, including: obtaining a to-be-measured sample; generating an average model; calculating a point correspondence of a spatial location formed by the average model and each to-be-measured sample; measuring each to-be-measured sample on the average model; and outputting feature parameter data of each to-be-measured sample in batch.

The generating an average model includes: reading point coordinates of all to-be-measured models, to generate a point cloud set of the to-be-measured models; selecting a point cloud with a maximal number of points from the point cloud set of the to-be-measured models as a reference point cloud; aligning the rest of to-be-measured point clouds to the reference point cloud; calculating, through affine transformation, a point correspondence between the aligned to-be-measured cloud point and the reference point cloud; calculating corresponding points, on each to-be-measured point cloud, of the reference point cloud according to the point correspondence, to generate a corresponding point set; and calculating an average value of the corresponding point sets, and generating the average model by using a surface reconstruction method.

The calculating a point correspondence of a spatial location formed by the average model and to-be-measured sample includes: calculating point correspondences between the average model and the all to-be-measured models.

The measuring each to-be-measured sample on the average model includes: manually marking a point set on the average model; calculating a corresponding mark point set on each to-be-measured sample for each point in the point set; calculating a measured value on the average model according to a mark point; and calculating a measured value on each to-be-measured sample according to a corresponding point.

The calculating a corresponding mark point set on each sample for each point in the point set includes: manually marking the mark point on the average model; constructing a KDTree on a point cloud of the average model; calculating a point that is in the average model and that is closest to the mark point by using the KDTree and the mark point, and recording an index of the point; storing the index of each mark point, and a corresponding transformation relationship between the average model and the to-be-measured sample; and calculating the mark point of the to-be-measured sample with reference to the index of the mark point on the average model according to the point correspondence between the average model and the to-be-measured sample.

According to another aspect, the present disclosure provides an apparatus for implementing batch extraction of human anatomical feature parameters, including: an obtaining module, configured to obtain a to-be-measured sample; a generation module, configured to generate an average model; a calculation module, configured to calculate a point correspondence of a spatial location formed by the average model and each to-be-measured sample; a measurement module, configured to measure each to-be-measured sample on the average model; and an output module, configured to output feature parameter data of each to-be-measured sample in batch.

The average model is generated by the generation module in the following manner: reading point coordinates of all to-be-measured models, to generate a point cloud set of the to-be-measured models; selecting a point cloud with a maximal number of points from the point cloud set of the to-be-measured models as a reference point cloud; aligning the rest of to-be-measured point clouds to the reference point cloud; calculating, through affine transformation, a point correspondence between the aligned to-be-measured cloud point and the reference point cloud; calculating corresponding points, on each to-be-measured point cloud, of the reference point cloud according to the point correspondence, to generate a corresponding point set; and calculating an average value of the corresponding point sets, and generating the average model by using a surface reconstruction method.

The point correspondence of the spatial location formed by the average model and to-be-measured sample is calculated by the calculation module in the following manner: calculating point correspondences between the average model and the all to-be-measured models.

Each to-be-measured sample is measured on the average model by the measurement model in the following manner: manually marking a point set on the average model; calculating a corresponding mark point set on each to-be-measured sample for each point in the point set; calculating a measured value on the average model according to a mark point; and calculating a measured value on each to-be-measured sample according to a corresponding point.

The corresponding mark point set on each sample is calculated for each point in the point set by the measurement model in the following manner: manually marking the mark point on the average model; constructing a KDTree on a point cloud of the average model; calculating a point that is in the average model and that is closest to the mark point by using the KDTree and the mark point, and recording an index of the point; storing the index of each mark point, and a corresponding transformation relationship between the average model and the to-be-measured sample; and calculating the mark point of the to-be-measured sample with reference to the index of the mark point on the average model according to the point correspondence between the average model and the to-be-measured sample.

It can be learned that, through the method and the apparatus for implementing batch extraction of human anatomical feature parameters, calculation time is reduced by combining feature point extraction with affine transformation, and corresponding points are calculated through a non-rigid registration method to achieve batch and quick measurement.

### BRIEF DESCRIPTION OF THE DRAWINGS

In order to describe the technical solutions in the embodiments of the present disclosure more clearly, the accompanying drawings required for describing the embodiments are briefly described below. Obviously, the accompanying drawings in the following description show merely some embodiments of the present disclosure, and a person of ordinary skill in the art would also be able to derive other accompanying drawings from these accompanying drawings without creative efforts.

FIG. 1 is a flowchart of a method for implementing batch extraction of human anatomical feature parameters according to an embodiment of the present disclosure;

FIGS. 2A-2E are schematic diagrams of a constructed average model according to an embodiment of the present disclosure;

FIG. 3 is a flowchart of a method for specifically implementing batch parameter generation on an average model according an embodiment of the present invention;

FIGS. 4A-4B are schematic diagrams of a mark point on an average model and a corresponding point of a to-be-measured sample according an embodiment of the present invention;

FIGS. 5A-5B are schematic diagrams of outputting data in batch according to an embodiment of the present disclosure; and

FIG. 6 is a schematic diagram of a structure of an apparatus for implementing batch extraction of human anatomical feature parameters according to an embodiment of the present disclosure.

### DETAILED DESCRIPTION OF THE EMBODIMENTS

Exemplary embodiments of the present disclosure will be described below in more detail with reference to the accompanying drawings. Although the accompanying drawings show exemplary embodiments of the disclosure, it should be understood that the present disclosure may be implemented in various forms and should not be limited to the embodiments set forth herein. On the contrary, these embodiments are provided so that the present disclosure will be more fully understandable, and will fully convey the scope of the present disclosure to those skilled in the art.

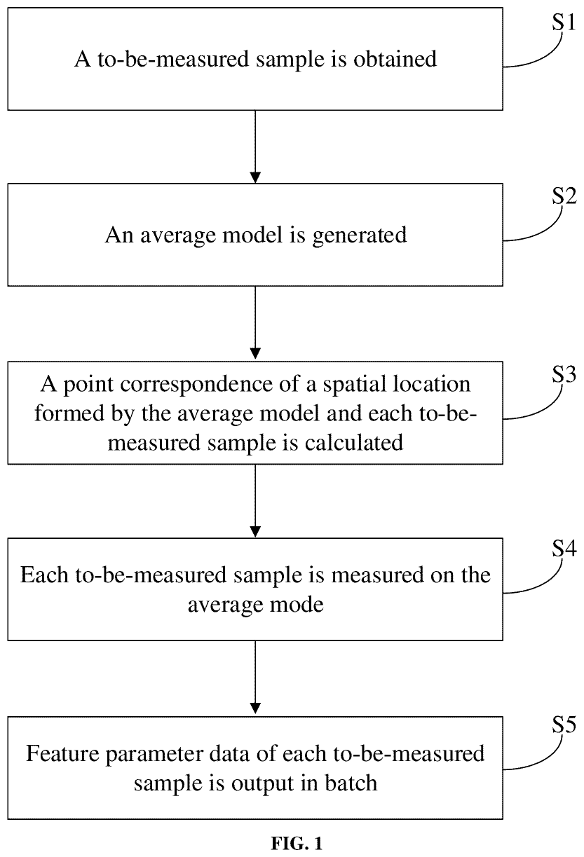

FIG. 1 is a flowchart of a method for implementing batch extraction of human anatomical feature parameters according to an embodiment of the present disclosure. Refer to FIG. 1, the method for implementing batch extraction of human anatomical feature parameters includes the following steps.

S1: A to-be-measured sample is obtained.

Specifically, the to-be-measured sample is pre-collected.

S2: An average model is generated.

Specifically, the average model is an average value of all to-be-measured three-dimensional models, and is more representative in form. A calculation idea of the average model is as follows: A point correspondence between the to-be-measured models is calculated; an average value of corresponding points is calculated based on the point correspondence, and point cloud data of the average model is generated; and the point cloud data is converted into a three-dimensional model by using a surface reconstruction method.

In an optional implementation of an embodiment of the present disclosure, that an average model is generated includes: Point coordinates of all to-be-measured models are read to generate a point cloud set of the to-be-measured models; a point cloud with a maximal number of points is selected from the point cloud set of the to-be-measured models as a reference point cloud; the rest of to-be-measured point clouds are aligned to the reference point cloud; a point correspondence between the aligned to-be-measured cloud point and the reference point cloud is calculated through affine transformation; corresponding points, on each to-be-measured point cloud, of the reference point cloud are calculated according to the point correspondence, to generate a corresponding point set; and an average value of the corresponding point sets is generated, and the average model is generated by using a surface reconstruction method.

During specific implementation, a calculation process of the average model includes the following steps.

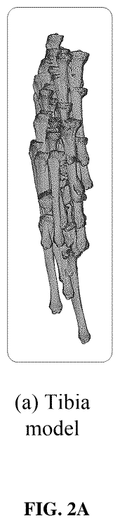

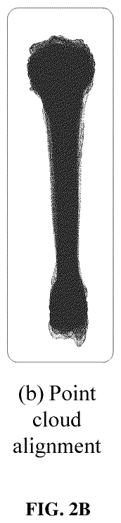

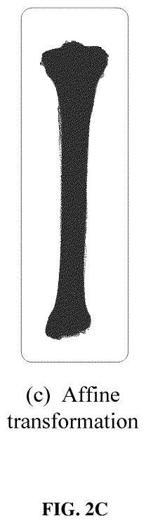

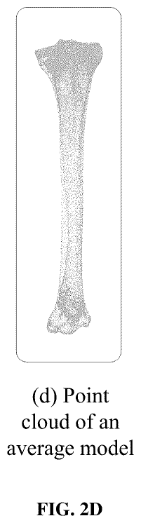

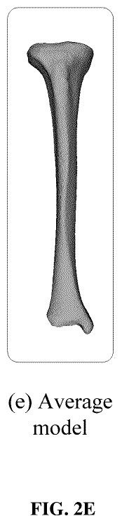

(1) Point coordinates of all to-be-measured models are read to generate a point cloud set of the to-be-measured models. (One to-be-measured model corresponds to one point cloud). As shown in FIG. 2A.

(2) A point cloud with a maximal number of points is selected from the point cloud set of the to-be-measured models as a reference point cloud.

(3) The rest of to-be-measured point clouds are aligned to the reference point cloud, as shown in FIG. 2B.

(4) A point correspondence between the aligned to-be-measured cloud point and the reference point cloud is calculated through affine transformation. An affine transformation result is shown in FIG. 2C.

(5) Corresponding points, on each to-be-measured point cloud, of the reference point cloud are calculated according to the point correspondence, to generate a corresponding point set.

(6) An average value of the corresponding point sets is calculated, as shown in FIG. 2D, and the average model is generated by using a surface reconstruction method, as shown in FIG. 2E.

This can be specifically implemented in the following manner.

Input: A to-be-measured three-dimensional model set X={x₁, x₂ . . . xₙ} is input, where Xᵢ is an i^{th} to-be-measured three-dimensional model.

Output: An average model a, and a corresponding transformation relationship V between the average model and all to-be-measured three-dimensional models are output.

(1) Points of all to-be-measured models are read to form a to-be-measured point cloud set P={p₁, p₂ . . . pₙ}.

(2) A point cloud with a maximal number of points is selected from P as a reference point cloud b.

(3) A corresponding point cloud set C={ }, on a to-be-measured point cloud, of the reference point cloud is obtained.

(4) For i=1 to n−1:

pᵢ′→ICP (pᵢ, b), pᵢ is used as a source point cloud, and b is used as a target point cloud for aligning.

s→FPFH (pᵢ′)t→FPFH (b), feature point extraction is performed on the to-be-measured point cloud and the target point cloud.

θ→AFFINE (s, t), affine transformation is performed and a transformation parameter is obtained.

cᵢ→corresponding points, on the to-be-measured point cloud, of the reference point cloud are calculated according to Pᵢ′, v, and θ.

C→ {cᵢ}, the corresponding points are added into a corresponding point cloud set. End for.

(5) a→an average point cloud of C is calculated, and surface reconstruction is performed.

(6) for i=1 to n:

vᵢ→BcpdNonrRigideMatch (a, xᵢ), a corresponding transformation relationship vᵢ between A and xᵢ is calculated through a BCPD non-rigid registration method.

V→ {vᵢ}, vᵢ is added into V.

End for.

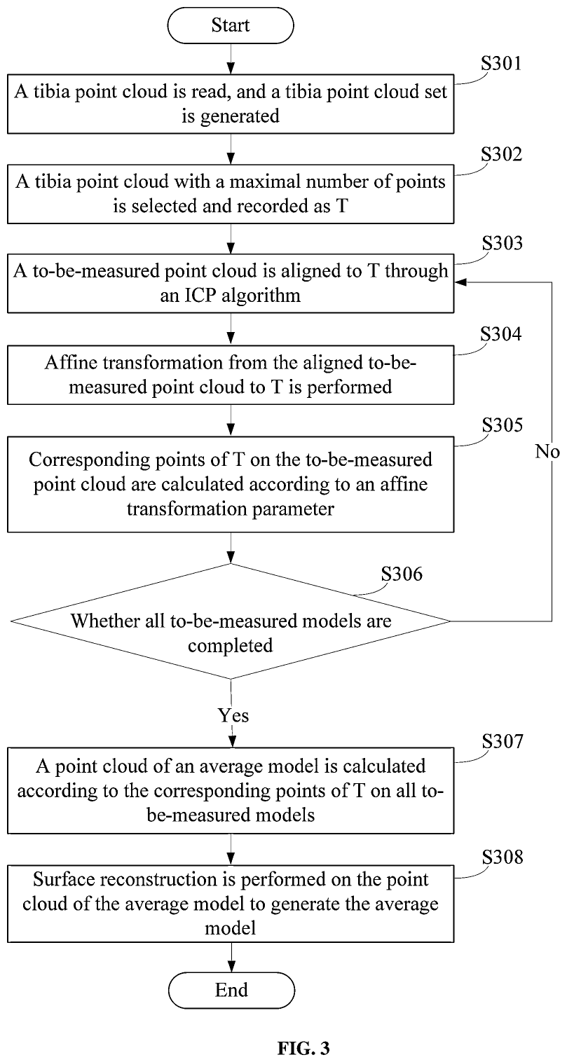

For example, as shown in FIG. 3, a process for generating an average model for a tibia is further described below.

A tibia point cloud is read to generate a tibia point cloud set (S301).

A tibia point cloud with a maximal number of points is selected as a reference point cloud which is recorded as T (S302).

The to-be-measured point cloud is aligned to the reference point cloud T through an ICP algorithm (S303).

Affine transformation from the aligned to-be-measured point cloud to the reference point cloud T is performed (S304).

Corresponding points, on the to-be-measured point cloud, of the reference point cloud T are calculated according to an affine transformation parameter (S305).

It is determined whether all to-be-measured models have been processed according to all of the above steps (S306); if yes, a point cloud of an average model is calculated according to corresponding points, on all to-be-measured models, of the reference point cloud T (S307); and surface reconstruction is performed on the point cloud of the average model to generate the average model (S308); and if no, a step of aligning the to-be-measured point cloud to the reference point cloud through the ICP algorithm is returned.

S3: A point correspondence of a spatial location formed by the average model and each to-be-measured sample is calculated.

In an optional implementation of this embodiment of the present disclosure, that a point correspondence of a spatial location formed by the average model and to-be-measured sample is calculated includes: Point correspondences between the average model and all to-be-measured models are calculated.

S4: Each to-be-measured sample is measured on the average model.

Specifically, after the transformation relationship between the average model and the to-be-measured sample is obtained through calculation, measurement of each to-be-measured sample can be implemented according to the point correspondence.

In an optional implementation of this embodiment of the present disclosure, that each to-be-measured sample is measured on the average model includes: A point set is manually marked on the average model; a corresponding mark point set on each to-be-measured sample is calculated for each point in the point set; a measured value is calculated on the average model according to the mark point; and a measured value is calculated on each to-be-measured sample according to a corresponding point.

In an optional implementation of this embodiment of the present disclosure, that a corresponding mark point set on each sample is calculated for each point in the point set includes: The mark point is manually marked on the average model; a KDTree is constructed on a point cloud of the average model; a point that is in the average model and that is closest to the mark point is calculated by using the KDTree and the mark point, and an index of the point is recorded; the index of each point, and a corresponding transformation relationship between the average model and the to-be-measured sample are stored; and the mark point of the to-be-measured sample is calculated with reference to the index of the mark point on the average model according to the point correspondence between the average model and the to-be-measured sample.

During a specific implementation, a batch measurement implementation process includes the following steps.

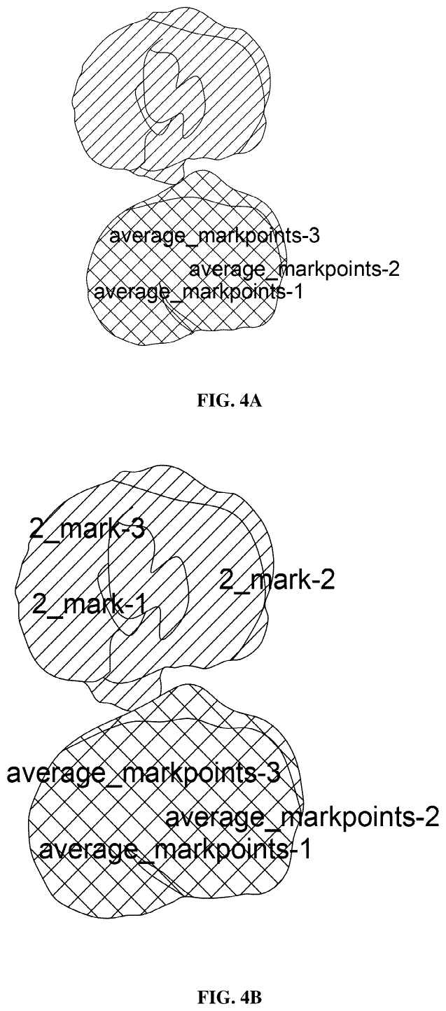

(1) A point set is manually marked on an average model, as shown in FIG. 4A.

(2) A corresponding mark point set on each sample is calculated in a manner of calculating a corresponding point on a to-be-measured sample for each point in the point set. As shown in FIG. 4B, average_markpoints-1 corresponds to 2_mark-1 (where 2 indicates two to-be-measured samples). In FIGS. 4A-4B, the top side is the average model, and the bottom side is the to-be-measured sample.

(3) A measured value is calculated on the average model according to the mark point.

(4) A measured value is calculated on each to-be-measured sample according to a corresponding point.

The corresponding point on the to-be-measured sample is calculated in the following manner.

Input: A point cloud x of the average model, and a transformation relationship V are input.

Output: A corresponding point set Pset on each sample is output.

(1) A mark point p is manually marked on the average model.

(2) KDTree reconstruction is performed on a point cloud of the average model.

(3) A point that is in x and that is closest to p is calculated by a KDTree and p, and index idx of the point is recorded.

(4) n: a quantity of to-be-measured samples is obtained.

(5) Pset={ }//A corresponding mark point of each sample is stored.

(6) for i=1 to n:

$${p}^{′} = p + V [ i ] [ i d x ] .$$

Pset→ {p′}, a corresponding point on an i^{th} sample is recorded into the set Pset. End for.

S5: Feature parameter data of each to-be-measured sample is output in batch.

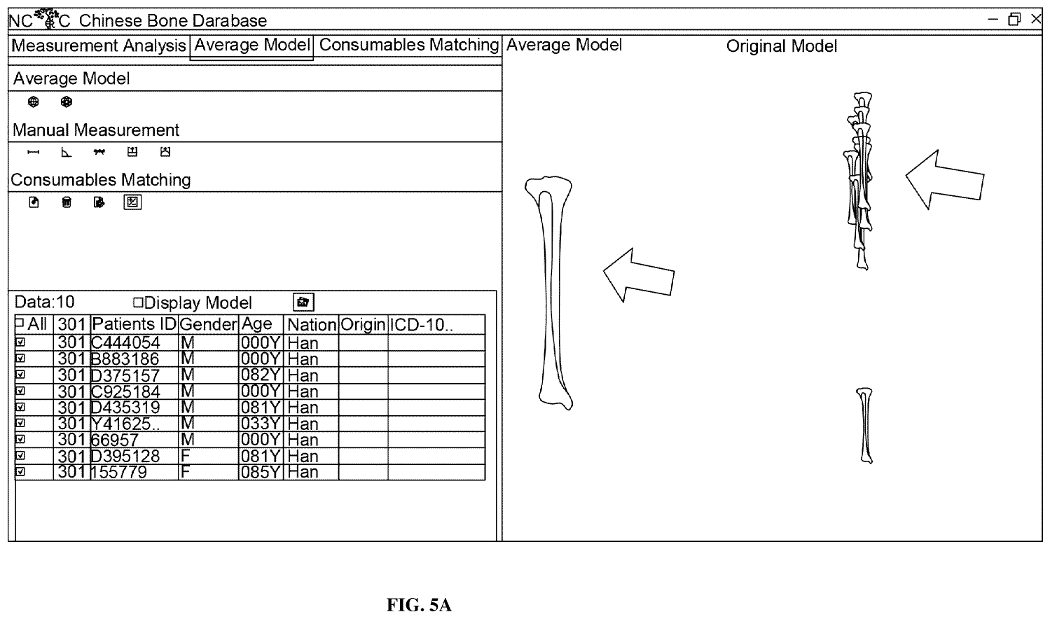

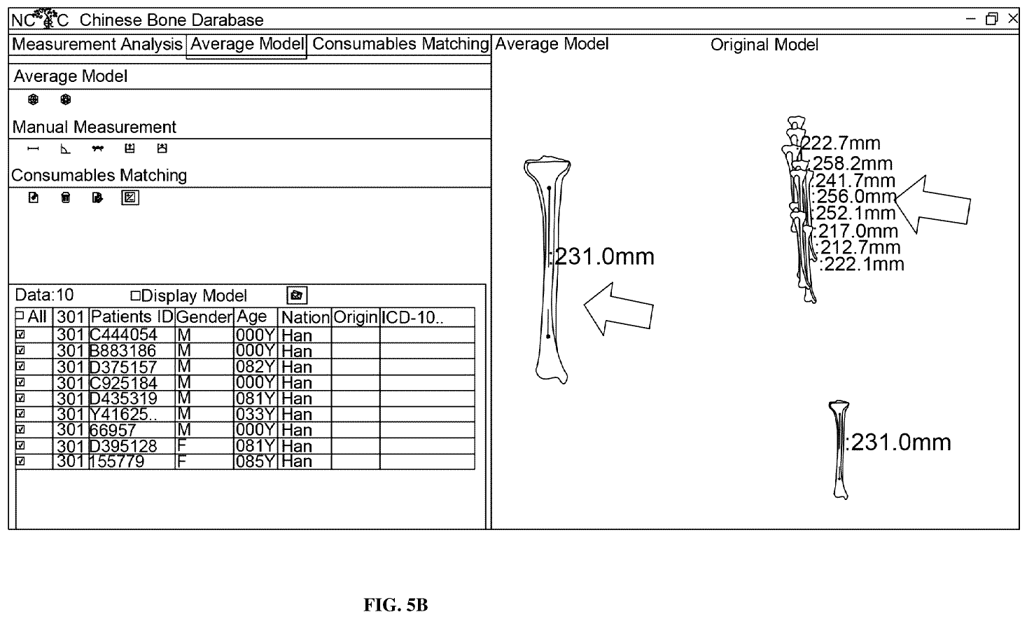

Specifically, refer to FIGS. 5A-5B. The average model (on the left side in FIG. 5A) is generated by the sample (on the right side in FIG. 5A). When any parameter (Line on the average model in FIG. 5B) is measured on the average model, a corresponding generated sample (on the right side in FIG. 5B) can be measured, to finally output data in batch.

It can be learned that, through the method for implementing batch extraction of human anatomical feature parameters according to an embodiment of the present disclosure, calculation time is reduced by combining feature point extraction with affine transformation, and corresponding points are calculated through a non-rigid registration method to achieve batch and quick measurement.

In addition, the disclosed method has the following advantages:

Compared to traditional manual measurement, in the method of the present disclosure, the point cloud based registration is used to improve measurement accuracy, avoiding the subjectivity and nonrepeatability in the manual measurement process that can lead to a decrease in measurement results.

Compared to traditional manual measurement, in the method of the present disclosure, measurement results are output in batch, solving the problem of low measurement efficiency caused by sequential measurement in manual measurement.

In the method of the present disclosure, the use of three-dimensional (3D) modeling for anatomical parameter measurement can avoid the problem of inaccurate measurement results caused by differences in patient positions in two-dimensional image measurement.

In some embodiments, the to-be-measured samples are three-dimensional models of to-be-measured tibias. In some embodiments, the feature parameter data of the to-be-measured samples is tibia crest curves of to-be-measured tibias. The tibia crest curve includes an inner crest curve, an outer crest curve, a posterior inner crest curve, and a posterior outer crest curve. The method may further include the following steps.

The tibia crest curves of the to-be-measured tibias are classified by using a clustering algorithm.

A crest curve average form of each category is calculated, to obtain a plurality of crest curve average forms.

A target tibia crest curve of a patient is obtained.

One of the crest curve average forms that has a highest similarity with the target tibia crest curve is selected as a target crest curve average form. The highest similarity is determined using the clustering algorithm.

A target tibia three-dimensional model for the patient is created based on the target crest curve average form. The Computer Aided Design (CAD) can be used to construct the target tibia three-dimensional model.

An implantable medical device of a tibia for the patient is manufactured based on the target tibia three-dimensional model by using 3D printer.

Traditionally, patients need to purchase the implantable medical device of a tibia that have been made on the market, which may result in incompatible. The disclosed method can design a tibia three-dimensional model for patients based on their own conditions, in order to create the suitable implantable medical device of a tibia.

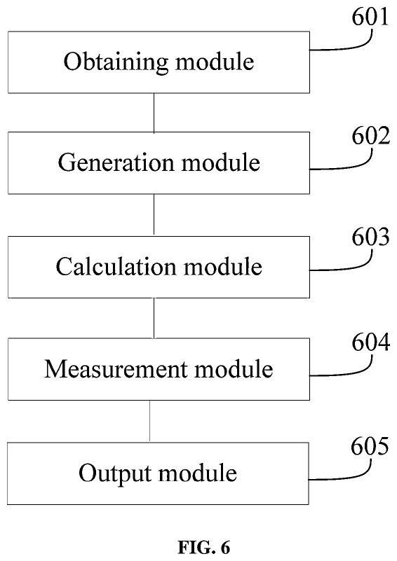

FIG. 6 is a schematic diagram of a structure of an apparatus for implementing batch extraction of human anatomical feature parameters according to an embodiment of the present disclosure. The apparatus for implementing batch extraction of human anatomical feature parameters adopts the method. The structure of the apparatus for implementing batch extraction of human anatomical feature parameters is only simply described below. For other details, refer to the related description in the method for implementing batch extraction of human anatomical feature parameters. Refer to FIG. 6, the apparatus for implementing batch extraction of human anatomical feature parameters includes an obtaining module 601, a generation module 602, a calculation module 603, a measurement module 604, and an output module 605.

The obtaining module 601 is configured to obtain a to-be-measured sample.

The generation module 602 is configurated to generate an average model.

The calculation module 603 is configured to calculate a point correspondence of a spatial location formed by the average model and each to-be-measured sample.

The measurement module 604 is configured to measure each to-be-measured sample on the average model.

The output module 605 is configured to output feature parameter data of each to-be-measured sample in batch.

In an optional implementation of this embodiment of the present disclosure, the average model is generated by the generation module in the following manner: Point coordinates of all to-be-measured models are read; a point cloud with a maximal number of points is selected from the point cloud set of the to-be-measured models as a reference point cloud; the rest of to-be-measured point clouds are aligned to the reference point cloud; a point correspondence between the aligned to-be-measured cloud point and the reference point cloud is calculated through affine transformation; corresponding points, on each to-be-measured point cloud, of the reference point cloud are calculated according to the point correspondence, to generate a corresponding point set; and an average value of the corresponding point sets is calculated, and the average model is generated by using a surface reconstruction method.

In an optional implementation of this embodiment of the present disclosure, the point correspondence of the spatial location formed by the average model and to-be-measured sample is calculated by the calculation module in the following manner: Point correspondences between the average model and the all to-be-measured models are calculated.

In an optional implementation of this embodiment of the present disclosure, each to-be-measured sample is measured on the average model by the measurement model in the following manner: A point set is manually marked on the average model; a corresponding mark point set on each sample is calculated for each point in the point set; a measured value on the average model is calculated according to a mark point; and a measured value on each to-be-measured sample is calculated according to a corresponding point.

In an optional implementation of this embodiment of the present disclosure, the corresponding mark point set on each sample is calculated for each point in the point set by the measurement model in the following manner: The mark point is manually marked on the average model; a KDTree is constructed on a point cloud of the average model; a point that is in the average model and that is closest to the mark point is calculated by using the KDTree and the mark point, and an index of the point is recorded; the index of each point, and a corresponding transformation relationship between the average model and the to-be-measured sample are stored; and the mark point of the to-be-measured sample is calculated with reference to the index of the mark point on the average model according to the point correspondence between the average model and the to-be-measured sample.

It can be learned that, through the apparatus for implementing batch extraction of human anatomical feature parameters according to an embodiment of the present disclosure, calculation time is reduced by combining feature point extraction with affine transformation, and corresponding points are calculated through a non-rigid registration method to achieve batch and quick measurement.

The above described are merely preferred embodiments of the present disclosure, which are not intended to limit the present disclosure. Various changes and modifications can be made to the present disclosure by those skilled in the art. Any modifications, equivalent replacements, improvements, etc. made within the spirit and principle of the present disclosure should be included within the protection scope of the claims of the present disclosure.

What is claimed is:

1. A method for implementing batch extraction of human anatomical feature parameters, comprising:
obtaining a point cloud set of a plurality of to-be-measured samples;
generating an average model based on the point cloud set;
calculating a point correspondence of a spatial location formed by the average model and each to-be-measured sample;
measuring the feature parameter of the average model and obtaining value of the feature parameter of each to-be-measured sample based on a measured value of the feature parameter of the average model; and
outputting the value of the feature parameter of each to-be-measured sample in batch.

2. The method according to claim 1, wherein the generating an average model comprises:
selecting a point cloud with a maximal number of points from the point cloud set of the to-be-measured models as a reference point cloud;
aligning the rest of to-be-measured point clouds to the reference point cloud;
calculating, through affine transformation, a point correspondence between the aligned to-be-measured cloud point and the reference point cloud;
calculating corresponding points, on each to-be-measured point cloud, of the reference point cloud according to the point correspondence, to generate a corresponding point set; and
calculating an average value of the corresponding point sets, and generating the average model by using a surface reconstruction method.

3. The method according to claim 2, wherein the calculating a point correspondence of a spatial location formed by the average model and to-be-measured sample comprises:
calculating point correspondences between the average model and the all to-be-measured models.

4. The method according to claim 3, wherein the measuring each to-be-measured sample on the average model comprises:
manually marking a point set on the average model;
calculating a corresponding mark point set on each to-be-measured sample for each point in the point set;
calculating a measured value on the average model according to a mark point; and
calculating a measured value on each to-be-measured sample according to a corresponding point.

5. The method according to claim 4, wherein the calculating a corresponding mark point set on each sample for each point in the point set comprises:
manually marking the mark point on the average model;
constructing a KDTree on a point cloud of the average model;
calculating a point that is in the average model and that is closest to the mark point by using the KDTree and the mark point, and recording an index of the point;
storing the index of each mark point, and a corresponding transformation relationship between the average model and the to-be-measured sample; and
calculating the mark point of the to-be-measured sample with reference to the index of the mark point on the average model according to the point correspondence between the average model and the to-be-measured sample.

6. The method according to claim 1, wherein the to-be-measured samples are three-dimensional models of to-be-measured tibias, the values of feature parameters of the to-be-measured samples form tibia crest curves of to-be-measured tibias, and the method further comprise:
classifying the tibia crest curves of the to-be-measured tibias by using a clustering algorithm;
calculating a crest curve average form of each category, to obtain a plurality of crest curve average forms;
obtaining a target tibia crest curve of a patient;
selecting one of the crest curve average forms that has a highest similarity with the target tibia crest curve as a target crest curve average form;
creating a target tibia three-dimensional model for the patient based on the target crest curve average form; and
manufacturing an implantable medical device of a tibia for the patient based on the target tibia three-dimensional model by using 3D printer.

7. An apparatus for implementing batch extraction of human anatomical feature parameters, comprising:
an obtaining module, configured to obtain a point cloud set of a plurality of to-be-measured samples;
a generation module, configured to generate an average model based on the point cloud set;
a calculation module, configured to calculate a point correspondence of a spatial location formed by the average model and each to-be-measured sample;
a measurement module, configured to measure the feature parameter of the average model and obtaining value of the feature parameter of each to-be-measured sample based on a measured value of the feature parameter of the average model; and
an output module, configured to output the value of the feature parameter of each to-be-measured sample in batch.

8. The apparatus according to claim 7, wherein the average model is generated by the generation module in the following manner:
selecting a point cloud with a maximal number of points from the point cloud set of the to-be-measured models as a reference point cloud;
aligning the rest of to-be-measured point clouds to the reference point cloud;
calculating, through affine transformation, a point correspondence between the aligned to-be-measured cloud point and the reference point cloud;
calculating corresponding points, on each to-be-measured point cloud, of the reference point cloud according to the point correspondence, to generate a corresponding point set; and
calculating an average value of the corresponding point sets, and generating the average model by using a surface reconstruction method.

9. The apparatus according to claim 8, wherein the point correspondence of the spatial location formed by the average model and to-be-measured sample is calculated by the calculation module in the following manner:
calculating point correspondences between the average model and the all to-be-measured models.

10. The apparatus according to claim 9, wherein each to-be-measured sample is measured on the average model by the measurement model in the following manner:
manually marking a point set on the average model;
calculating a corresponding mark point set on each to-be-measured sample for each point in the point set;
calculating a measured value on the average model according to a mark point; and
calculating a measured value on each to-be-measured sample according to a corresponding point.

11. The apparatus according to claim 10, wherein the corresponding mark point set on each sample is calculated for each point in the point set by the measurement model in the following manner:
manually marking the mark point on the average model;
constructing a KDTree on a point cloud of the average model;
calculating a point that is in the average model and that is closest to the mark point by using the KDTree and the mark point, and recording an index of the point;
storing the index of each mark point, and a corresponding transformation relationship between the average model and the to-be-measured sample; and
calculating the mark point of the to-be-measured sample with reference to the index of the mark point on the average model according to the point correspondence between the average model and the to-be-measured sample.

12. The apparatus according to claim 7, wherein the to-be-measured samples are three-dimensional models of to-be-measured tibias, the values of feature parameters of the to-be-measured samples form tibia crest curves of to-be-measured tibias, and the apparatus further comprise:
a classifying module, configured to classify the tibia crest curves of the to-be-measured tibias by using a clustering algorithm;
a curve calculation module, configured to calculate a crest curve average form of each category, to obtain a plurality of crest curve average forms;
a target obtaining module, configured to obtain a target tibia crest curve of a patient;
a selection module, configured to select one of the crest curve average forms that has a highest similarity with the target tibia crest curve as a target crest curve average form;
a creation module, configured to create a target tibia three-dimensional model for the patient based on the target crest curve average form; and
an manufacturing module, configured to manufacturing an implantable medical device of a tibia for the patient based on the target tibia three-dimensional model by using 3D printer.
